(19) United States
(12) Patent Application Publication
(10) Pub. No.: US 2004/0118516 A1
(43) Pub. Date: Jun. 24, 2004

(54) Plasma parameter control using learning data

(76) Inventors: Gunter Grasshoff, Radebeul (DE); Christoph Schwan, Gebhardshain (DE); Matthias Schaller, Dresden (DE)

Correspondence Address: J. Mike Amerson, Williams, Morgan & Amerson, P.C., Suite 1100, 10333 Richmond, Houston, TX, 77042, US

(21) Appl. No.: 10/462,932

(22) Filed: Jun. 16, 2003

(30) Foreign Application Priority Data
Dec. 23, 2002 (DE) 102 60 614.5

(51) Int. Cl. H01L 21/306

(52) U.S. Cl. 156/345.24

(57) ABSTRACT

A plasma control apparatus, a plasma etch system and a method of controlling plasma parameters in a production process are provided that may be used for performing real time measurements that relate to at least one physical or chemical property of a plasma. Learning data is generated that indicates at least one expected range for process run data. Process run data is received during the production process, wherein the process run data indicates current values of at least one plasma parameter. The plasma parameter of the production process is controlled based on the received process run data and the learning data.

### BACKGROUND OF THE INVENTION

1. Field of the Invention

This invention generally relates to the generation of a plasma, and, more particularly, to the control of plasma parameters.

2. Description of the Related Art

Manufacturers in the electronic sectors, and, in particular, the semiconductor manufacturers, use plasma technology for a variety of surface modifications and etching applications.

A plasma is a mixture of electrically charged and neutral particles, including electrons, atoms, ions and free radicals, and occurs only under certain environmental circumstances. It reacts with a wide variety of substances, and can be used to clean, etch or coat almost any surface without great safety efforts and liquid waste associated with other processes.

During a plasma etch process, it is important to accurately determine an etch depth and to have stable process conditions. Etch depth monitoring, in its simplest form, may comprise calibrating a process and then simply timing the etch run. However, run-to-run etch rate variations of up to 10% may be expected using this method. A more accurate etch depth may be obtained by etching for three quarters of the predicted etch time, measuring the etch depth and then predicting the time required to finish the etch. This has, however, the major drawback of being time-consuming and therefore expensive. Other common etch depth monitoring techniques are based on the fact that there is, in most cases, a change in the spectral composition of the light emitted by the plasma when the plasma comes into contact with an underlying surface during the etch process. Basically, the optical plasma emission reacts on the change in the chemical composition and/or electrical characteristic of the discharge due to the fact of contacting an interface layer.

Stable process conditions are crucial to achieve stable process results. Current conventional plasma tool setups detect only in-limit conditions of direct-controlled process parameters, e.g., power, gas flows or pressures. Other deviations of parameters which are more closely related to the plasma process are usually not watched and analyzed during a process run.

Because of the above-mentioned problems, an increasing number of conventional plasma tool setups do not provide a reliable detection performance and may not be able to guarantee stable process results. FIG. 1 illustrates a conventional plasma etch apparatus 100 that substantially comprises two electrodes 110, 140 mounted in a plasma generation reactor 100, wherein one electrode 140 is connected to a ground and the other electrode 110 is connected to an RF (radio frequency) generator 170. The RF generator 170 is adapted to generate an RF power to apply an electrical field across the electrodes 110 and 140. The wafer 130 that is to be plasma etched is placed on the electrode 140. The plasma etch apparatus 100 further comprises a gas inlet valve 160 and a gas outlet valve 150 to provide a gas flow for establishing a gas concentration and pressure in the plasma generation reactor 100. The conventional plasma etch apparatus 100 of FIG. 1 may be only adapted to detect an in-limit condition of the direct-controlled process parameters, wherein an in-limit condition is a situation when process parameters do not exceed predefined values of process parameters.

It is difficult to adjust the parameters to have stable process conditions because of process variations and long-term drifts of the process properties. Moreover, when a substrate varies, for instance, in thickness, misprocessing and yield loss may increasingly become possible because the process tool is not able to adjust all the process conditions to keep the process stable.

### SUMMARY OF THE INVENTION

The present invention is directed to various methods and systems that may solve, or at least reduce, some or all of the aforementioned problems. In particular, a plasma control apparatus, a plasma etch apparatus and a method of controlling plasma parameters are provided that may be used to improve the stability of plasma process conditions.

In one embodiment, there is provided a plasma control apparatus for controlling at least one plasma parameter in a production process. The apparatus comprises a real time measurement analyzer for performing real time measurements that relate to at least one physical or chemical property of a plasma. The apparatus further comprises a plasma parameter controller that is connected to receive process run data during the production process. The process run data indicates current values of at least one plasma parameter. The plasma parameter controller is further connected to the real time measurement analyzer for receiving learning data. The learning data indicates at least one expected range for the process run data. The plasma parameter controller is adapted for controlling at least one plasma parameter of the production process based on the process parameter run data and the learning data.

In a further embodiment, there is provided a plasma etch system for manufacturing a semiconductor structure. The plasma etch system comprises an etch plasma processing equipment that is adapted for generating an etch plasma. The plasma etch system further comprises a real time measurement analyzer for performing real time measurements that relate to at least one physical or chemical property of an etch plasma and an etch plasma parameter controller that is connected to receive etch process run data during the production process. The etch process run data indicates current values of the at least one etch plasma parameter. The etch plasma parameter controller is further connected to the real time measurement analyzer for receiving learning data. The learning data indicates at least one expected range for the etch process run data. The etch plasma parameter controller is adapted for controlling at least one etch plasma parameter of the production process based on the etch process parameter run data and the learning data.

In another embodiment, there is provided a method of controlling plasma parameters in a production process. The method comprises performing real time measurements that relate to at least one physical or chemical property of a plasma for generating learning data that indicates at least one expected range for process run data. The method further comprises receiving process data during the production process. The process run data indicates current values of at least one plasma parameter. The method further comprises controlling at least one plasma parameter of the production process based on the received process run data and the learning data.

### BRIEF DESCRIPTION OF THE DRAWINGS

The invention may be understood by reference to the following description taken in conjunction with the accompanying drawings, in which like reference numerals identify like elements, and in which:

FIG. 1 shows a conventional plasma etch apparatus;

FIG. 2 is a block diagram illustrating a plasma control apparatus for controlling plasma parameters according to one illustrative embodiment of the present invention;

FIG. 3 is a flowchart illustrating a plasma parameter controlling process according to another illustrative embodiment of the present invention; and

FIG. 4 is a block diagram illustrating a plasma control apparatus for controlling plasma parameters according to a further illustrative embodiment of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures of a semiconductor device are depicted in the drawings as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

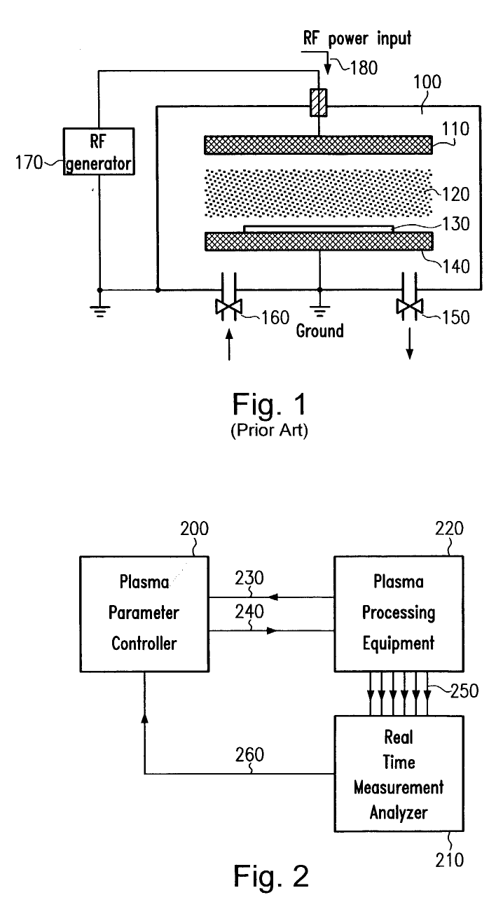

Referring now to the drawings, FIG. 2 is a block diagram of a plasma control apparatus according to one illustrative embodiment of the present invention. The plasma control apparatus comprises a plasma parameter controller 200 and a real time measurement analyzer 210. The real time measurement analyzer 210 is connected to plasma processing equipment 220 and is adapted for performing real time measurements that relate to physical and/or chemical properties of a plasma generated in the plasma processing equipment 220. The plasma processing equipment 220 of the present embodiment may be substantially arranged as shown in FIG. 1.

The physical or chemical properties of the plasma 120 may be, e.g., an optical emission spectrum, a gas flow parameter or composition, an electrical parameter, for instance, a bias voltage, etc. The real time measurement analyzer 210 is further adapted for generating learning data. The learning data comprises learning data items that indicate expected ranges of the above-mentioned physical and/or chemical plasma properties, wherein measured values related to the physical or chemical properties of the plasma may be considered as plasma parameters.

The plasma parameter controller 200 is connected to the plasma processing equipment 220 to receive process run data during a production process and to transmit a controller response to the plasma processing equipment 220, wherein the process run data indicates current values of plasma parameters of the plasma processing equipment 220. The plasma parameter controller 200 is further connected to receive learning data from the real time measurement analyzer 210 via a connection 260, wherein the real time measurement analyzer 210 is arranged to apply a statistical algorithm to generate the learning data. The plasma parameter controller 200 may compare the process run data with the learning data and generate plasma parameter control signals based on the comparison result. If the comparison result indicates that the process run data does not fall within a corresponding expected range, the plasma parameter controller then transmits controller response signals to the plasma processing equipment 220 to warn for long-term drifts of process properties or a malfunction of the plasma processing equipment 220.

According to another illustrative embodiment, the plasma parameter controller 200 comprises a data processing system that is adapted for processing the process run data and learning data to generate the controller response signals for controlling the plasma parameters. The data processing system is further adapted for storing and updating the learning data, wherein the learning data is statistical data that comprises values of an expected plasma process parameter collected over a predetermined time period of the production process.

As is apparent from the foregoing, the present embodiment comprises a data processing system, wherein the data processing system comprises a neural network according to a further embodiment.

In yet another illustrative embodiment, the plasma parameter controller 200 is further adapted for initiating a plasma parameter correction process when the process run data does not fall within a corresponding expected range. If the process run data does not fall within the corresponding expected range, then the plasma parameter controller 200 transmits a warning message indicating a long-term drift of the process properties or a malfunction of the plasma processing equipment 220. In a further illustrative embodiment, the plasma parameter correction process initiates a stop procedure to terminate an operation of the plasma processing equipment 220.

While in the discussion above the plasma control apparatus was described as comprising the plasma parameter controller 200 and the real time measurement analyzer 210, a plasma etch apparatus may further comprise the plasma processing equipment 220. As can be seen from FIG. 2, the plasma etch apparatus has several interconnections, wherein the connection 230 is provided to transmit process run data to the plasma parameter controller 200. The connection 240 is provided to deliver a controller response generated by the plasma parameter controller 200 to the plasma processing equipment 220.

As can be further seen, the plasma etch apparatus 200, 210, 220 provides an interconnection 250 connecting the plasma processing equipment 220 with the real time measurement analyzer 210. As mentioned above, the real time measurement analyzer 210 performs real time measurements that relate to physical and/or chemical properties of the plasma 120 generated in the plasma processing equipment 220. The real time measurement analyzer 210 may be arranged to apply a statistical algorithm for generating learning data to be statistical data that is transmitted to the plasma parameter controller 200 by using the interconnection 260 between the real time measurement analyzer 210 and the plasma parameter controller 200.

The plasma parameter controller 200 of the plasma etch apparatus may initiate a plasma parameter correction process that comprises transmitting a controller response to the plasma process equipment 220 for every process step in a predefined time resolution.

Accordingly, the real time measurement analyzer 210 may be arranged for generating the learning data during a specific learning period before the production process starts. In another illustrative embodiment, the learning data is continuously generated by the real time measurement analyzer 210 during the production process.

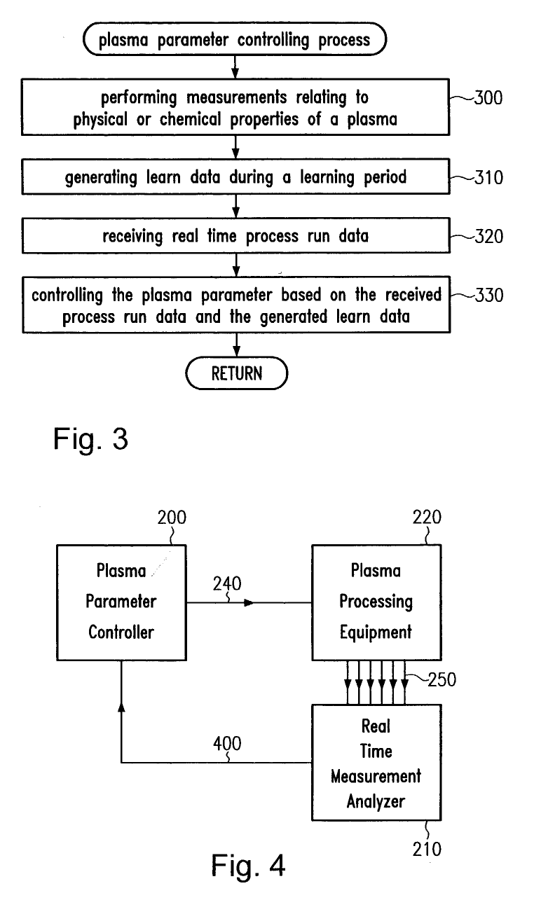

Turning now to FIG. 3, the flowchart illustrates a plasma parameter controlling process according to an illustrative embodiment of the present invention. As described therein, the illustrative plasma parameter controlling process comprises, in step 300, performing the measurements that are related to physical or chemical properties of the plasma generated in the plasma processing equipment 220. Measurement values resulting from the above-described process step 300 may depend on the substrate to be processed, the process used, and the measurement time point in the process run. Step 310 of the plasma parameter controlling process comprises the generation of the learning data during a learning period according to one illustrative embodiment of the present invention. As mentioned above, according to another illustrative embodiment, the real time measurement analyzer 210 is arranged for generating the learning data simultaneously with the production process.

Still discussing the embodiment of FIG. 3, step 320 of the plasma parameter controlling process comprises the reception of the real time process run data, wherein the real time process run data indicates current values of the plasma parameter that may depend on the substrate to be processed, the process used, the current state of the plasma processing equipment 220, and a time point in the process run.

As described above, the plasma parameter controller 200 is adapted for controlling one or more plasma parameters of the production process based on the process parameter run data and the learning data. In correspondence thereto, step 330 of the plasma parameter controlling process comprises the step of controlling the plasma parameter based on the received process run data and the generated learning data.

In a further illustrative embodiment, step 330 of controlling the plasma parameter further comprises the initiation of a plasma parameter correction process that comprises a stop procedure to terminate the operation of the plasma processing equipment 220 when the process run data does not fall within a corresponding expected range of the statistical data.

According to another illustrative embodiment of the present invention, the plasma parameter controlling process may comprise two phases. The two phases may be a learning phase and an execution phase, wherein the learning phase may comprise the given steps of 300 and 310, and the execution phase may comprise the given steps of 320 and 330, as shown in FIG. 3.

According to a further illustrative embodiment, the plasma parameter controlling process may comprise a learning phase, wherein a step of acquiring the plasma parameter may be performed according to a representative process sequence, in order to generate a process model for modeling a plasma process based on learning data. The plasma parameter controlling process may further comprise an execution phase, wherein the measurement data may be evaluated in a real time process under consideration of the position of the measurement data related to an approved measurement data range to initiate a correction process. The correction process may initiate a correction of values that have influence on the performance of the production process in case of process property drifts and/or in case the production process is stopped, wherein, in both cases, the above-mentioned process model may be adapted.

Turning now to FIG. 4, a block diagram of a plasma system is shown according to another illustrative embodiment of the present invention. The system of FIG. 4 may differ from the plasma control apparatus of FIG. 2 in that no connection 230 is provided to transmit process run data to the plasma parameter controller 200. Instead, the connection 400 of the plasma control apparatus of FIG. 4 allows for transmitting the measured real time process run data from the real time measurement analyzer 210 to the plasma parameter controller 210 during the process run, in addition to transmitting learning data during the learning period.

As is apparent from the foregoing description, all of the illustrative embodiments as described may advantageously provide stable plasma process conditions to achieve stable plasma process results.

Furthermore, the above-described technique provides the advantage to reduce material jeopardy and to reduce the costs of manufacturing the respective devices. This is because the arrangements improve reliability, the precision and the accuracy of plasma parameters in the production process.

Further, a function is provided that has shorter response times in case of a malfunction of the plasma processing equipment 220. This is because the arrangements provide a better process control and therefore achieve an improvement of the material quality processed by the plasma processing equipment 220.

While, usually, a process result is evaluated after performing a full process run in which all of the products are completely processed, the above-described embodiments advantageously provide the possibility to detect a malfunction during a process run. This effects a lower yield loss rate and leads to the additional advantage of allowing for correcting values that have influence on the process run. Further, the process may be stopped early enough to avoid great misprocessing.

The principle of all the described illustrative embodiments may be based on the use of measurements with more direct relation to the physical and/or chemical property of the plasma 120 in the plasma processing equipment 220 (e.g., measurements of the optical emission spectrum or electrical parameters, such as a bias voltage, and measurements by a plasma diagnostic system such as Self Excited Electron Resonance Spectroscopy (SEERS)). The production process may be analyzed in terms of the resulting response, i.e., the process run data, for every process step with a predefined time resolution. The generated learning data may be fed to the data processing system, which uses a neuronal network approach or an adequate data analyzing system to get a statistical proven “normal” response for a given plasma parameter in relation to the substrate to be processed, the process used and the time point in the process run.

After the system has performed a learning period, the system can advantageously decide whether a current plasma parameter is within the statistical expected range indicated by the learning data for this point of time within the process run or not. Based on this analysis, the system can send out information to the plasma processing equipment 220 in the case of non-expected process run data to stop processing as a result of an equipment malfunction or incoming material change. So, the above systems can advantageously be used as real time fault detection systems for the plasma processing equipment. Moreover, the systems can also contribute to tightening up the process variations and can warn in case of long-term drifts of process properties.

The above-described embodiments may be substantially used for performing process and tool checks, wherein process and tool checks comprise post-processing result measurements (e.g., etch depth or critical dimension measurements) on respective products, and tool process parameter in-limit checks during the processing (mostly global for one process defined via deviations from settings). Further, other tests, e.g., etch rate checks or profile checks, may be used. Further, the above-described embodiments may be substantially used to control an etch process and for checking the health of the process during the run to reduce risks for yield loss due to hardware drifts and defectivity.

As described above, a plasma etch system may be provided that may comprise a plasma parameter based processing facility, a real time measurement system and an analyzer and/or evaluation system, wherein the real time measurement system may be adapted for determining plasma property values.

According to a further illustrative embodiment, the real time measurement analyzer 210 may acquire etch plasma data that may be statistically evaluated by the etch plasma parameter controller 200 during a learning period. The statistical evaluation may result in data that may comprise data items, e.g., an expected plasma parameter value and a lower and/or upper threshold value for each respective parameter. The threshold value range may be centered at an average value and may have a width of three times the standard deviation. The statistical evaluation may comprise the usage of a neural network by using example (correct and defective) processing. Due to a given systematical dependency (e.g., different products, different process setup conditions or the like) of the parameters, and due to a general parameter dependency of a property to be processed, the data may need to be categorized in accordance to those dependencies to be handled separately. This may cause the necessity to also evaluate and acquire not only the current measurement data but also the relation of the current measurement data to the product and to the process as well as the time structure (e.g., the time in a process step in different process levels). After the learning period, the currently acquired measurement data may be compared in a real time comparison process with the statistically evaluated learning data. If the current measurement data drifts out of the range of the above-mentioned threshold values, a predefined action of the system will be initiated.

According to an illustrative embodiment, the term “plasma parameter” may indicate both values that are directly or indirectly related to the plasma properties and process parameters that may indicate values that control the process run.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A plasma control apparatus for controlling at least one plasma parameter in a production process, the apparatus comprising:
a real time measurement analyzer for performing real time measurements relating to at least one physical or chemical property of a plasma; and
a plasma parameter controller connected to receive process run data during said production process, said process run data indicating current values of said at least one plasma parameter, said plasma parameter controller being further connected to said real time measurement analyzer for receiving learning data, said learning data indicating at least one expected range for said process run data;
wherein said plasma parameter controller is adapted for controlling said at least one plasma parameter of said production process based on said process parameter run data and said learning data.

2. The apparatus of claim 1, wherein said plasma parameter controller comprises a data processing system for processing said process run data and said learning data to generate signals for controlling said at least one plasma parameter.

3. The apparatus of claim 2, wherein said data processing system comprises a neural network.

4. The apparatus of claim 2, wherein said data processing system is further adapted for storing and updating said learning data.

5. The apparatus of claim 4, wherein said learning data is statistical data that comprises at least one value of an expected plasma process parameter.

6. The apparatus of claim 1, wherein said plasma parameter controller is further adapted for initiating a plasma parameter correction process when said process run data does not fall within a corresponding expected range.

7. The apparatus of claim 1, wherein said plasma parameter controller is connected to plasma processing equipment capable of generating said plasma, wherein said plasma parameter controller is further adapted for transmitting a controller response to said plasma processing equipment.

8. The apparatus of claim 7, wherein said plasma parameter controller is further adapted to transmit said controller response for every process step with a predefined time resolution.

9. The apparatus of claim 1, wherein said plasma parameter controller is further connected to plasma processing equipment capable of generating said plasma, wherein said plasma parameter controller is further adapted for initiating a stop procedure to stop an operation of said plasma processing equipment.

10. The apparatus of claim 1, wherein said real time measurement analyzer is arranged to apply a statistical algorithm for generating said learning data.

11. The apparatus of claim 1, wherein said process run data depends on the substrate to be processed, the process used and a time point in the process run.

12. The apparatus of claim 1, wherein said plasma parameter controller is adapted to transmit a warning massage to said plasma processing equipment capable of generating said plasma in case of long-term drifts of process properties.

13. The apparatus of claim 1, wherein said real time measurement analyzer is arranged for generating said learning data during a specific learning period before said production process.

14. The apparatus of claim 1, wherein said plasma parameter controller is further adapted for comparing said process run data with said learning data and for generating plasma parameter control signals based on the comparison result.

15. The apparatus of claim 14, wherein said plasma parameter controller is further adapted for performing said comparison in real time.

16. The apparatus of claim 1, wherein said at least one plasma parameter is an etch plasma parameter.

17. The apparatus of claim 1, wherein said production process is a semiconductor device manufacturing process.

18. A plasma etch system for manufacturing a semiconductor structure, said plasma etch system comprising:
etch plasma processing equipment adapted for generating an etch plasma;
a real time measurement analyzer for performing real time measurements relating to at least one physical or chemical property of said etch plasma; and
an etch plasma parameter controller connected to receive etch process run data during said production process, said etch process run data indicating current values of said at least one etch plasma parameter, said etch plasma parameter controller being further connected to said real time measurement analyzer for receiving learning data, said learning data indicating at least one expected range for said etch process run data;
wherein said etch plasma parameter controller is adapted for controlling said at least one etch plasma parameter of said production process based on said etch process parameter run data and said learning data.

19. A method of controlling plasma parameters in a production process, the method comprising:
performing real time measurements relating to at least one physical or chemical property of a plasma for generating learning data indicating at least one expected range for process run data;
receiving process run data during said production process, said process run data indicating current values of said at least one plasma parameter; and
controlling said at least one plasma parameter of said production process based on the received process run data and said learning data.

20. The method of claim 19, wherein the step of controlling comprises transmitting a warning massage to plasma processing equipment capable of generating said plasma in case of long-term drifts of process properties.

21. The method of claim 19, wherein the step of controlling comprises initiating a plasma parameter correction process when said process run data does not fall within a corresponding expected range.

22. The method of claim 21, wherein said plasma parameter correction process comprises a stop procedure to stop an operation of said plasma processing equipment capable of generating said plasma.

23. The method of claim 21, wherein said plasma parameter correction process comprises a controller response to said plasma process equipment capable of generating said plasma for every process step with a predefined time resolution.

24. The method of claim 21, wherein generating said learning data comprises applying a statistical algorithm by the real time measurement analyzer.

25. The method of claim 19, wherein receiving said process run data depends on the substrate to be processed, the process used and a time point in the process run.

26. The method of claim 19, further comprising updating and storing said learning data by a data processing system arranged for processing said process run data and said learning data to generate signals for controlling said at least one plasma parameter.

27. The method of claim 26, wherein said learning data is statistical data that has data items of at least one expected plasma process parameter.

28. The method of claim 26, wherein said data processing system comprises a neural network.
